(19) United States
(12) Patent Application Publication
(10) Pub. No.: US 2024/0213084 A1
(43) Pub. Date: Jun. 27, 2024

(54) APPARATUSES INCLUDING SHALLOW TRENCH ISOLATION AND METHODS FOR FORMING SAME

(71) Applicant: MICRON TECHNOLOGY, INC., BOISE, ID (US)

(72) Inventors: Maxtheodore Tateno, Higashihiroshima (JP); Takashi Sasaki, Higashihiroshima (JP)

(73) Assignee: MICRON TECHNOLOGY, INC., BOISE, ID (US)

(21) Appl. No.: 18/536,026

(22) Filed: Dec. 11, 2023

Related U.S. Application Data
(60) Provisional application No. 63/477,276, filed on Dec. 27, 2022.

(51) Int. Cl. H01L 21/762; H01L 21/02

(52) U.S. Cl. CPC H01L 21/76232; H01L 21/02164; H01L 21/0217

(57) ABSTRACT

A semiconductor structure includes a trench in a substrate, one or more spacers at a bottom surface of the trench, and spin-on dielectric in the trench.

### CROSS-REFERENCE TO RELATED APPLICATIONS

This application claims the filing benefit of U.S. Provisional Application No. 63/477,276, filed Dec. 27, 2022. This application is incorporated by reference herein in its entirety and for all purposes.

### BACKGROUND

As semiconductor devices become highly integrated, alignment of device elements during fabrication becomes more difficult. For example, in a semiconductor memory device, such as a dynamic random access memory (DRAM) device, a memory cell region is isolated from a peripheral region including a peripheral circuit around the memory cell region, by an isolation region. An example isolation region includes a trench filled with a dielectric material (e.g., a shallow trench isolation, STI). The spacing requirements for memory arrays often require the isolation trenches to have relatively narrow widths. Such isolation trenches are typically filled with spin-on-dielectrics (SODs) in liquid form and densified by curing or annealing, for example by a steam-oxidation process. However, the densification process can induce strain on the surface edges of the isolation trenches. As a result, misalignment or overlay issues may arise, for example, misalignment of a bit line (or a digit line) in the memory cell region near the isolation trench from a digit line contact plug.

Therefore, isolation regions including trenches and filler material with reduced edge strain and methods for forming the same may be desirable.

### BRIEF DESCRIPTION OF THE SEVERAL VIEWS OF THE DRAWINGS

FIG. 1A is a plan view of a memory die of a semiconductor memory device according to an embodiment of the disclosure.

FIG. 1B is a plan view of a portion of the memory die along the line A-A′-A″ depicted in FIG. 1A.

FIG. 1C is a cross-sectional view of a portion of the memory die along the line A-A′-A″ depicted in FIG. 1A.

FIG. 2A is a cross-sectional view of a portion of a semiconductor structure including a shallow trench isolation (STI).

FIG. 2B is a cross-sectional view of a semiconductor structure including a STI according to an embodiment of the disclosure.

FIG. 3 is a process flow diagram of a method of forming a semiconductor structure according to an embodiment of the disclosure.

FIGS. 4A, 4C, 4D, 4E, 4F, and 4G are cross-sectional views of a portion of the semiconductor structure corresponding to various states of the method depicted in FIG. 3.

FIG. 4B is a plan view of a portion of the semiconductor structure corresponding to various states of the method depicted in FIG. 3.

To facilitate understanding, identical reference numerals have been used, where possible, to designate identical elements that are common to the figures. In the figures and the following description, an orthogonal coordinate system including an X-axis, a Y-axis, and a Z-axis is used. The directions represented by the arrows in the drawing are assumed to be positive directions for convenience. It is contemplated that elements disclosed in some embodiments may be beneficially utilized on other implementations without specific recitation.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with ordinary skill in the art so as not to obscure the description of embodiments of the disclosure. The following detailed description is therefore not to be taken in a limiting sense, and the scope of the disclosure is defined only by the appended claims.

The embodiments described herein provide shallow trench isolation (STI) structures that are filled with spin-on-dielectric (SOD), where the STI trench includes a structure formed therein to reduce a volume of the STI trench and methods for forming the same. Such structure may include one or more spacers and reduces a volume of the STI trench, and thus a volume of SOD filled in the STI trench. The SOD filled in the STI trench induces strain on the surface edges of the STI trench, but the strain is reduced by the reduced volume of the SOD as compared to SOD filled in a STI trench having no structure formed therein.

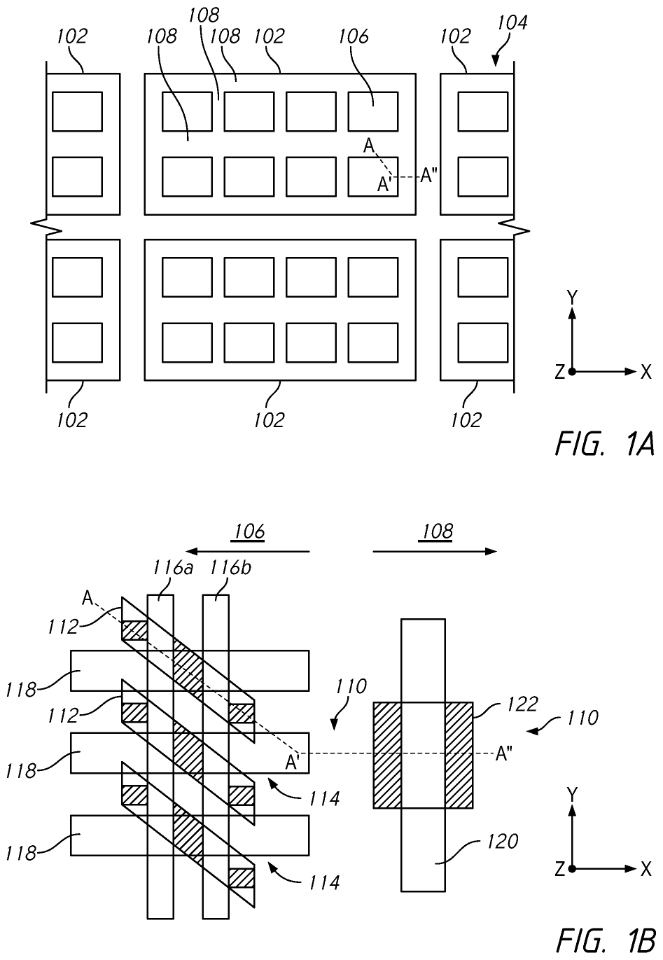

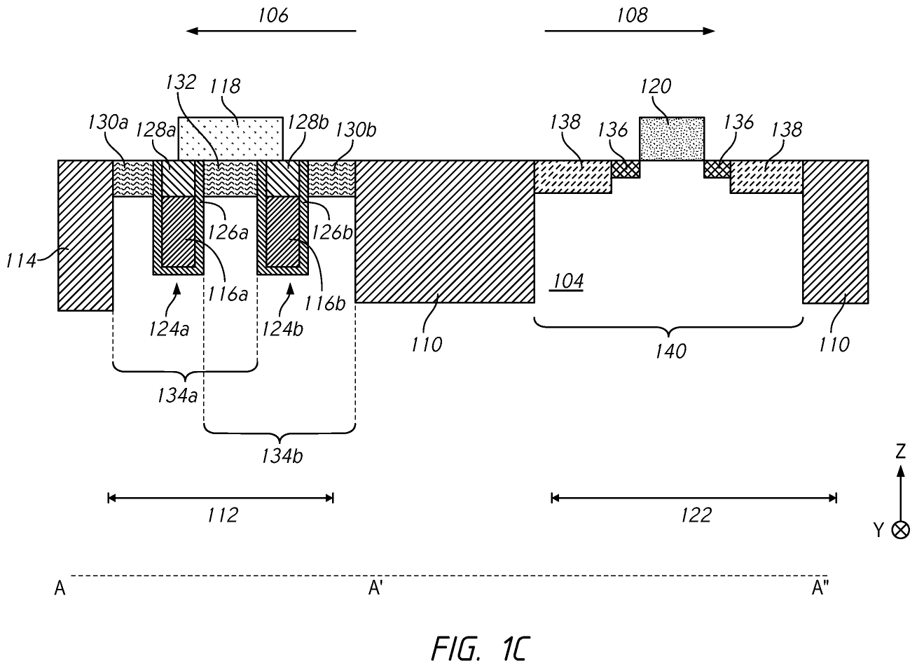

FIG. 1A is a plan view of a memory die 102 of a semiconductor memory device according to an embodiment of the disclosure. In the fabrication process, memory dies 102 (e.g., 200 memory dies 102) are formed in a matrix form on a surface of a substrate 104 and the substrate 104 is subsequently diced to separate individual memory dies 102. Each memory die 102 includes an array of memory cell regions 106 and peripheral regions 108 surrounding the memory cell regions 106,

FIG. 1B is a plan view of a portion of the memory die 102 along the line A-A′-A″ depicted in FIG. 1A, including a portion of a memory cell region 106, a portion of a peripheral region 108. The memory cell region 106 and the peripheral region 108 are isolated by an isolation region 110.

The memory cell region 106 includes active regions 112 that each extend in the direction along the line A-A′. The active regions 112 adjacent to each other in the Y-direction are separated by a memory cell isolation region 114. The memory cell region 106 further includes word lines 116a, 116b that each extend in the Y-direction and intersect the active regions 112, and bit lines 118 that each extend in the X-direction and intersect the word lines 116a, 116b.

The peripheral region 108 includes a gate electrode 120 formed within an active region 122.

FIG. 1C is a cross-sectional view of a portion of the memory die 102 along the line A-A′-A″ depicted in FIGS. 1A and 1B, including a portion of the memory cell region 106 and a portion of the peripheral region 108. The memory cell region 106 and the peripheral region 108 are isolated by the isolation region 110.

The memory cell region 106 includes trenches 124a, 124b having insulating films 126a, 126b therein that are formed within the substrate 104 to accommodate the word lines 116a, 116b, respectively. The word line 116a is buried within the trench 124a by a cap insulating film 128a. The word line 116b is buried within the trenches 124a by a cap insulating film 128b. The memory cell region 106 further include drain diffusion layers 130a, 130b and a source diffusion layer 132. In the active region 112, a transistor 134a having the word line 116a as a gate electrode, the drain diffusion layer 130a, and the source diffusion layer 132, and a transistor 134b having the word line 116b as a gate electrode, the drain diffusion layer 130b, and the source diffusion layer 132 are formed. The bit lines 118 that extend in the Y-direction are formed over the source diffusion layer 132.

The peripheral region 108 includes lightly-doped drain regions 136 and diffusion layers 138 that are outside of the lightly-doped drain regions 136. The gate electrode 120 is formed over the active region 122 between the lightly-doped drain regions 136. In the peripheral region 108, a transistor region 140 having the gate electrode 120 and the diffusion layers 138 as source/drain electrodes is formed.

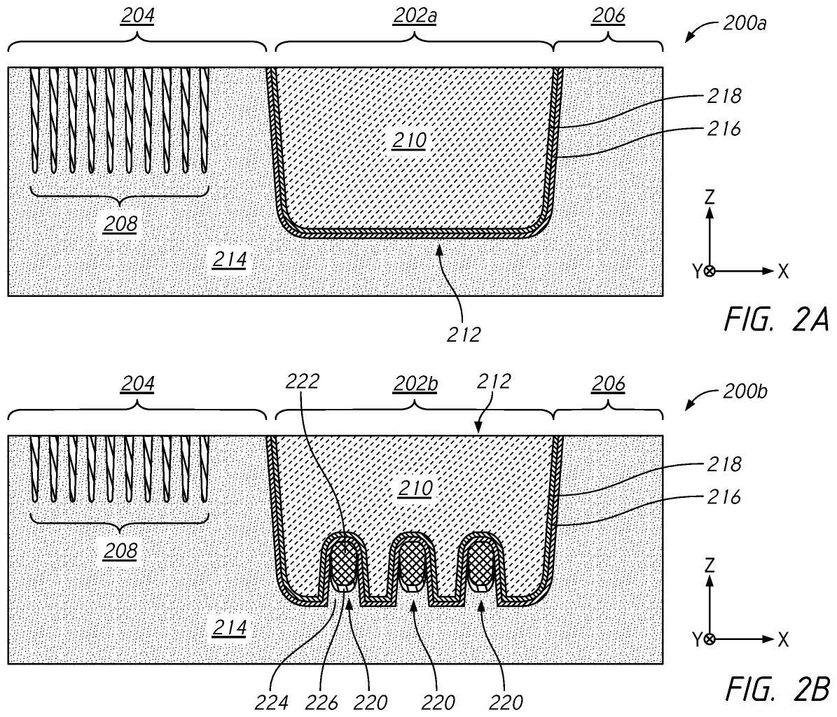

FIG. 2A is a cross-sectional view of a portion of a semiconductor structure 200a including a shallow trench isolation (STI) 202a. The STI 202a may be used as an isolation region, such as the isolation region 110 depicted in FIGS. 1A, 1B, and 1C, to isolate adjacent active regions 204, 206. The first active region 204 may include device elements 208 formed therein. In some embodiments, the device elements 208 may be the word lines 116a, 116b (shown in FIGS. 1B and 1C). The second active region 206 may include other device elements (not shown) formed therein. In some embodiments, the device elements in the second active region 206 may be the lightly-doped drain regions 136, diffusion layers 138 (shown in FIGS. 1B and 1C), and other periphery circuits.

The STI 202a is formed of a spin-on-dielectric (SOD) 210 filled in a STI trench 212 formed in a substrate 214. As shown, sidewalls of the STI trench 212 are oxidized, forming a thin oxide 216. The oxide 216 may repair any damages from a prior etch process to form the STI trench 212 in the substrate 214. The sidewalls of the STI trench 212 are further covered by a nitride liner 218. The nitride liner 218 may protect the adjacent active regions 204, 206 and act as an oxygen barrier between the substrate 214 and the SOD 210 in the STI trench 212 during the fabrication process. In some embodiments of the disclosure, the nitride liner 218 may have a thickness of about 10 Å and about 300 Å. The SOD 210 may be formed of dielectric material, such as a spin-on glass, perhydrosilazane (SiH₂NH), hydrogen silsesquioxane (HSQ, H₈Si₈O₁₂), hexamethyldisiloxane (HMDSO, O[Si(CH₃)₃]₂), octamethyltrisiloxane (C₈H₂₄O₂S₁₃), or the like.

FIG. 2B is a cross-sectional view of a semiconductor structure 200b including a STI 202b according to an embodiment of the disclosure. The STI 202b is similar to the STI 202a, but includes spacers 220 at a bottom surface of the STI trench 212. In FIG. 2B, three spacers 220 each extending in the Y-Z plane are shown. Each spacer 220 includes a nitride portion 222, a substrate portion 224, and an oxide portion 226 between the nitride portion 222 and the substrate portion 224. The number of spacers 220 may be less or more than three. The spacers 220 may have different shapes from the example shown in FIG. 2B. The spacers 220 may have different shapes or volumes from one another.

Each of the spacers 220 reduces a volume of the STI trench 212. Due to the spacers 220, the volume of the STI trench 212 in the STI 202b is reduced as compared to a volume of the STI trench 212 in the STI 202a of FIG. 2A. Thus, the volume of the SOD 210 filling the STI trench 212 is also reduced. By reducing the volume of the STI trench 212 and the volume of the SOD 210 filling the STI trench 212, strain on the edges of the STI trench 212 induced by the SOD 210 during its densification process may be reduced.

In some implementations, the STI trench 212 has a depth in the Z-direction of between about 300 nm and about 400 nm, for example, about 340 nm, and a width in the X-direction of between about 250 nm and about 400 nm, for example, about 350 nm. Each spacer 220 may have a height in the Z-direction of between about 170 nm and about 210 nm, for example, about 190 nm, and a width in the X-direction of between about 40 nm and about 60 nm, for example, about 50 nm. The nitride portion 222 may have a height in the Z-direction of between about 80 nm and about 100 nm, for example, about 90 nm. The substrate portion 224 may have a height in the Z-direction of between about 80 nm and about 100 nm, for example, about 90 nm. The substrate portion 224 is low in the Z-direction close to the bottom surface of the STI trench 212 such that the STI 202b provides sufficient isolation to avoid leakage current to the device elements 208.

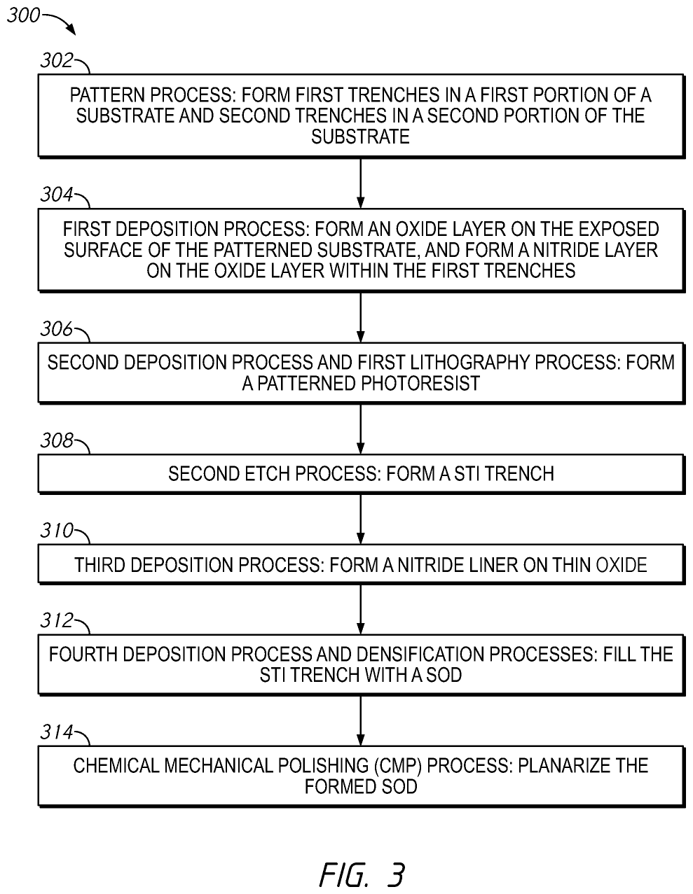

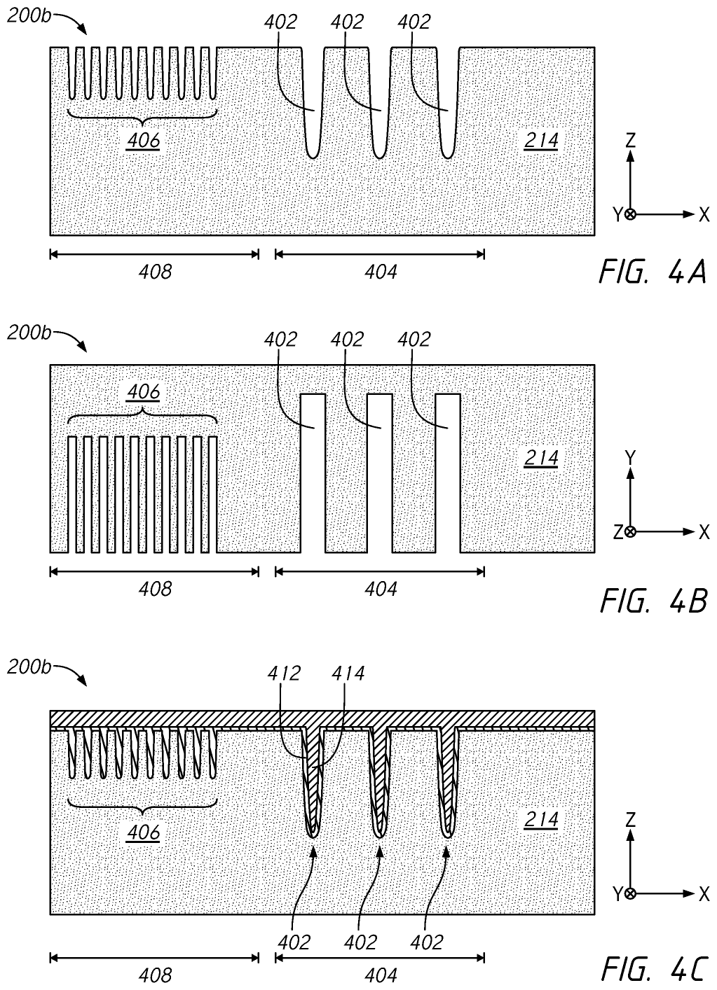

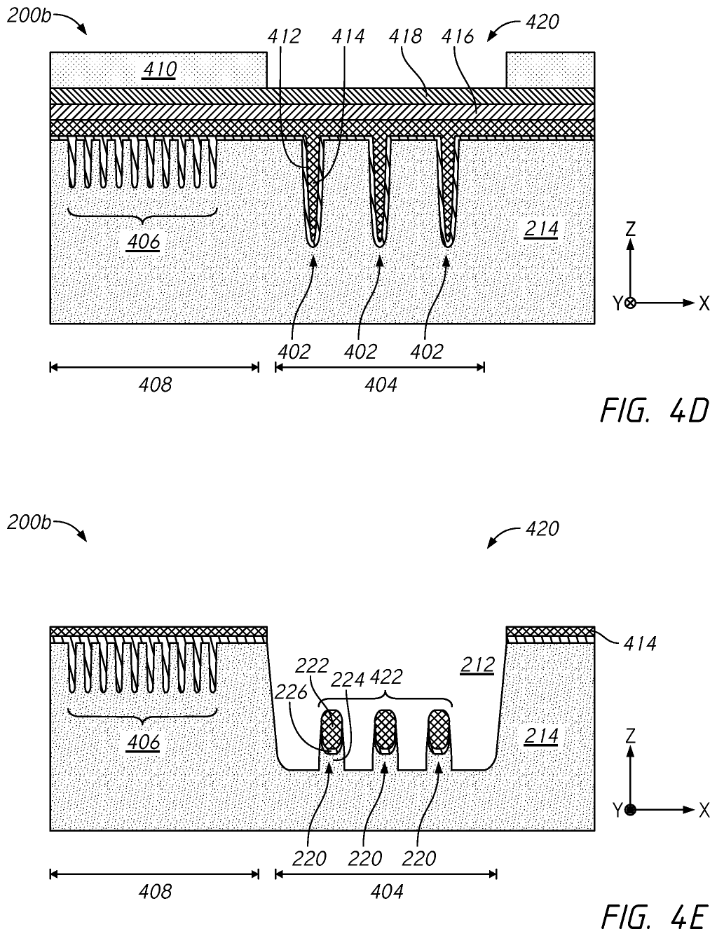

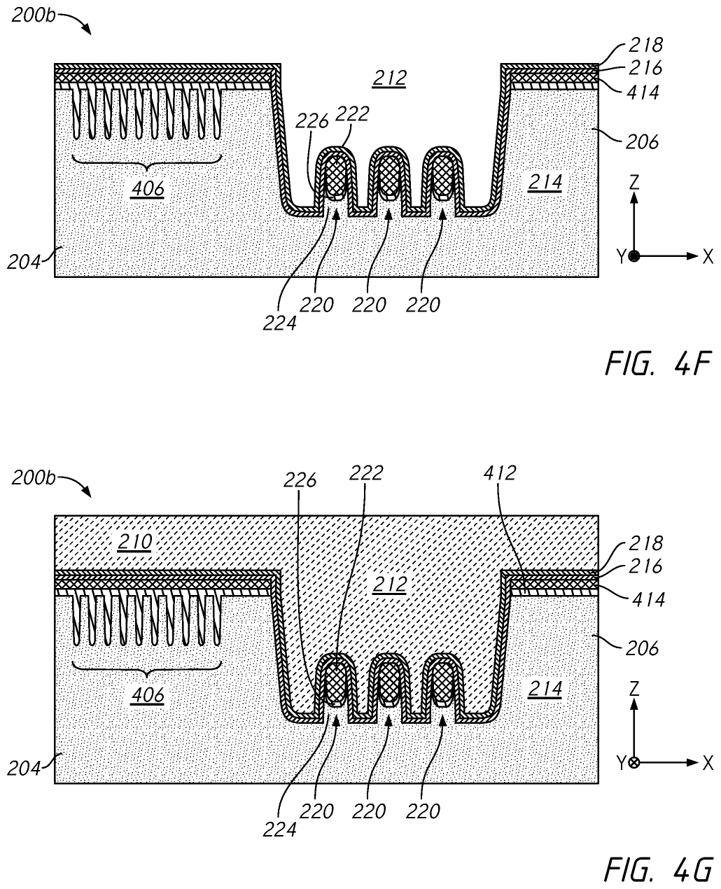

FIG. 3 is a process flow diagram of a method 300 of forming a semiconductor structure 200b including a STI, such as the STI 202b as shown in FIG. 2B, according to certain embodiments. FIGS. 4A, 4C, 4D, 4E, 4F, and 4G are cross-sectional views of a portion of the semiconductor structure 200b corresponding to various states of the method 300. FIG. 4B is a plan view of a portion of the semiconductor structure 200b corresponding to various states of the method depicted in FIG. 3. It should be understood that FIGS. 4A, 4B, 4C, 4D, 4E, 4F, and 4G illustrate only partial schematic views of the semiconductor structure 200b, and the semiconductor structure 200b may contain any number of transistor sections and additional materials having aspects as illustrated in the figures. It should also be noted although the method steps illustrated in FIG. 3 are described sequentially, other process sequences that include one or more method steps that have been omitted and/or added, and/or has been rearranged in another desirable order, fall within the scope of the embodiments of the present disclosure.

The method 300 begins with block 302, in which a pattern process is performed to form first trenches 402 in a first portion 404 of a substrate 214 and second trenches 406 in a second portion 408 of the substrate 214, as shown in FIGS. 4A and 4B. The pattern process may include a lithography process to form patterned photoresist on an exposed surface of the substrate 214, followed by a first etch process to remove material of the substrate 214. The first trenches 402 and second trenches 406 extend in the Y-Z plane. The second trenches 406 may be used to form memory cell isolation regions, for example, memory cell isolation regions 114 (e.g., shallow trench isolation) between adjacent active regions 112 (shown in FIGS. 1B and 1C), formed therein. The second trenches 406 may have a depth in the Z-direction of between about 200 nm and about 270 nm, for example, about 240 nm. In some implementations, the first trenches 402 have depth in the Z-direction of between about 200 nm and about 270 nm, for example, about 240 nm, and a width in the X-direction of between about 40 nm and about 60 nm, for example, about 50 nm.

The substrate 214 may be a silicon based material or any suitable insulating materials or conductive materials as needed. The substrate 214 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The substrate 214 may have various dimensions, such as 200 mm, 300 mm, 410 mm or other diameter wafers, as well as, rectangular or square panels. Unless otherwise noted, implementations and examples described herein are conducted on substrates with a 200 mm diameter, a 300 mm diameter, or a 410 mm diameter substrate.

The pattern process can be any appropriate lithography process forming a patterned photoresist on an exposed surface of the substrate 214. The first etch process is any appropriate etch process, such as reactive-ion etching.

In block 304, a first deposition process is performed to form an oxide layer 412 on the exposed surface of the patterned substrate 214, including inner walls of the first trenches 402 and the second trenches 406, and to form a nitride layer 414 on the oxide layer 412 within the first trenches 402, as shown in FIG. 4C. The oxide layer 412 may be formed of silicon-containing oxide, such as silicon oxide (SiO₂), and the nitride layer 414 may be formed of silicon-containing nitride, such as silicon nitride (Si₃N₄). The first deposition process may be performed using any appropriate deposition process, such as chemical vapor deposition (CVD), sputtering, spin-on, physical vapor deposition (PVD), or the like.

In block 306, a second deposition process and a first lithography process are performed to form a patterned photoresist 410 on the exposed surface of the semiconductor structure 200b, as shown in FIG. 4D. The second deposition process includes depositing an underlayer coating layer 416 on the exposed surface of the semiconductor structure 200b, an anti-reflective coating (ARC) layer 418 over the underlayer coating layer 416, and the photoresist 410 over the ARC layer 418. The second deposition process may be performed using any appropriate deposition process, such as chemical vapor deposition (CVD), sputtering, spin-on, physical vapor deposition (PVD), or the like. The underlayer coating layer 416 may be formed of tetraethoxysilane (TEOS), amorphous silicon (a-Si), silicon oxynitride (SiON), other suitable oxide material, other suitable carbide material, other suitable oxycarbide material, or other suitable oxynitride material. The ARC layer 418 may be formed of organic or inorganic silicon-containing antireflective material, such as silicon oxynitride (SiON), and may reduce light reflections in a subsequent lithographic process. The first lithography process is any appropriate lithography process to form an opening 420 in the photoresist 410 over the first trenches 402 in the first portion 404 of the substrate 214. In some implementations, the opening 420 has a width in the X-direction of between about 250 nm and about 400 nm.

In block 308, a second etch process is performed to form a STI trench 212, as shown in FIG. 4E. In the second etch process, the opening 420 of the photoresist 410 is transferred to the substrate 214 and the STI trench 212 is formed. Further, the nitride layer 414 (shown in FIG. 4D) acts as a mask layer such that portions of the substrate 214 are etched at a faster rate than the nitride layer 414, and thus spacers 220 each having a nitride portion 222 and a substrate portion 224 are formed within the STI trench 212. An oxide portion 226 from the oxide layer 412 (shown in FIG. 4D) remains between the nitride portion 222 that is unetched and the underlying substrate portion 224. The oxide portion 226 is on sidewalls and a bottom surface of the nitride portion 222. The spacers 220 reduce a volume of the STI trench 212. The second etch process is any appropriate etch process, such as reactive-ion etching. Subsequent to the second etch process, the remaining photoresist 410, ARC layer 418, and underlayer coating layer 416 are stripped, and the nitride layer 414 is partially etched resulting in reduced thickness. The exposed surface of the semiconductor structure 200b is cleaned by an appropriate wet etch process. In some implementations, the STI trench 212 has a depth in the Z-direction of between about 300 nm and about 400 nm, for example, about 340 nm, and a width in the X-direction of between about 250 nm and about 400 nm. Each spacer 220 may have a height in the Z-direction of between about 170 nm and about 210 nm, for example, about 190 nm, and a width in the X-direction of between about 40 nm and about 60 nm, for example, about 50 nm. The nitride portion 222 may have a height in the Z-direction of between about 80 nm and about 100 nm, for example, about 90 nm. The substrate portion 224 may have a height in the Z-direction of between about 80 nm and about 100 nm, for example, about 90 nm.

In block 310, a third deposition process is performed to form a nitride liner 218 on a thin oxide 216 on the exposed surface of the semiconductor structure 200b, as shown in FIG. 4F. The oxide 216 may be formed of silicon-containing oxide, such as silicon oxide (SiO₂) by thermal oxidation, on sidewalls and the bottom surface of the STI trench 212 and over the spacers 220. The oxide 216 may repair damages on the sidewalls of the STI trench 212 from the etch process in block 308. The nitride liner 218 may be formed of silicon-containing nitride, such as silicon nitride (Si₃N₄), by any appropriate deposition process, such as chemical vapor deposition (CVD), sputtering, spin-on, physical vapor deposition (PVD), or the like. The nitride liner 218 may protect active regions 204, 206 adjacent to the STI trench 212 from oxidation in a subsequent process of filling the STI trench 212.

Thickness of the oxide 216 may be between about 30 Å and 100 Å, and thickness of the nitride liner 218 may be between about 200 Å and 1500 Å.

In block 312, a fourth deposition process and a densification processes are performed to fill the STI trench 212 with a SOD 210, as shown in FIG. 4G. The fourth deposition process is a spin-on deposition process in which the SOD 210 in a liquid form is deposited on the exposed surface of the semiconductor structure 200b while the semiconductor structure 200b is rapidly spun such that the liquid is spread uniformly over the surface of the semiconductor structure 200b after low points (e.g., inside the STI trench 212) is filled. The spin-on deposition process is followed by the densification process that bakes and anneals the semiconductor structure 200b to densify the SOD 210. In some implementations, the SOD 210 is heated up to a temperature of about 1000° C. in a steam ambient. The SOD 210 may be formed of dielectric material, such as a spin-on glass, perhydrosilazane (SiH₂NH), hydrogen silsesquioxane (HSQ, H₈Si₈O₁₂), hexamethyldisiloxane (HMDSO, O[Si(CH₃)₃]₂), octamethyltrisiloxane (C₈H₂₄O₂Si₃), or the like. During the densification process, the volume of the SOD 210 filling the trench changes and introduces strains on the edges of the STI trench 212. With the spacers 220 reducing the volume of the STI trench 212, a volume of the SOD 210 in the STI trench 212 is also reduced and thus the strain caused by the SOD 210 may be reduced.

In block 314, a chemical mechanical polishing (CMP) process is performed to planarize the formed SOD 210 with top surfaces of the first active region 204 and the second active region 206, as shown in FIG. 2B. In the CMP process, portions of the SOD 210, the oxide layer 412, the nitride layer 414, the oxide 216, and the nitride liner 218 outside the STI trench 212 and an excess portion of the SOD 210 over the STI trench 212 are removed. The resulting STI 202b is shown in FIG. 2B.

In the embodiments described herein, shallow trench isolation (STI) structures in which surface strains caused by the filler material are reduced and methods for forming the same are provided. A STI structure according to the embodiments described herein includes a STI trench filled with spin-on-dielectric (SOD), where the STI trench includes a structure formed therein. The structure included in the STI trench reduces a volume of the STI trench. Strain caused by the SOD may be reduced by the reduced volume of SOD filling the STI trench as compared to SOD filling a conventional STI trench not having a structure formed therein. As a result, misalignment of device elements in an active region near the STI structure can be avoided.

From the foregoing it will be appreciated that, although specific embodiments of the disclosure have been described herein for purposes of illustration, various modifications may be made without deviating from the spirit and scope of the disclosure. Accordingly, the scope of the disclosure should not be limited any of the specific embodiments described herein.

What is claimed is:

1. A semiconductor structure, comprising:
a trench in a substrate;
one or more spacers at a bottom surface of the trench; and
spin-on dielectric in the trench.

2. The semiconductor structure of claim 1, wherein each of the one or more spacers comprises:
a substrate portion at the bottom surface of the trench;
a nitride portion on the substrate portion; and
an oxide portion on sidewalls and a bottom surface of the nitride portion.

3. The semiconductor structure of claim 2, wherein
the nitride portion comprises silicon nitride (Si₃N₄), and
the oxide portion comprises silicon oxide (SiO₂).

4. The semiconductor structure of claim 2, wherein
the trench has a depth of between 300 nm and 400 nm, and
each of the one or more spacers has a height of between 170 nm and 210 nm.

5. The semiconductor structure of claim 4, wherein
each of the one or more spacers has a width of between 40 nm and 60 nm.

6. The semiconductor structure of claim 4, wherein
the nitride portion has a height of between 80 nm and 100 nm, and
the substrate portion has a height of between 80 nm and 100 nm.

7. The semiconductor structure of claim 1, wherein the spin-on dielectric comprises perhydrosilazane (SiH₂NH).

8. The semiconductor structure of claim 1, further comprising:
an oxide on the bottom surface of the trench and over the one or more spacers; and
a nitride liner over the oxide.

9. A semiconductor structure, comprising:
a memory cell region;
a peripheral region;
an isolation region between the memory cell region and the peripheral region, wherein
the isolation region comprises spin-on dielectric filled in a trench in a substrate,
the trench having one or more spacers at a bottom surface of the trench.

10. The semiconductor structure of claim 9, wherein
the memory cell region comprises one or more word lines, and
the peripheral region comprises periphery circuits.

11. The semiconductor structure of claim 9, wherein each of the one or more spacers comprises:
a substrate portion at the bottom surface of the trench;
a nitride portion on the substrate portion; and
an oxide portion on sidewalls and a bottom surface of the nitride portion.

12. The semiconductor structure of claim 11, wherein
the nitride portion comprises silicon nitride (Si₃N₄), and
the oxide portion comprises silicon oxide (SiO₂).

13. A method of forming a semiconductor structure comprising:
forming one or more first trenches in a first portion of a substrate and one or more second trenches in a second portion of the substrate;
forming an oxide layer on inner walls of the one or more first trenches and the one or more second trenches;
forming a nitride layer on the oxide layer within the one or more first trenches; and
forming a shallow trench isolation (STI) trench in the first portion of the substrate, the first portion having the one or more first trenches with the oxide layer and the nitride layer formed therein.

14. The method of claim 13, wherein
the forming of the STI trench comprises:
a lithography process forming a photoresist having an opening in the first portion of the substrate, the first portion having the one or more first trenches with the oxide layer and the nitride layer formed therein;
an etch process etching the first portion of the substrate through the opening.

15. The method of claim 13, wherein
the oxide layer comprises silicon oxide (SiO₂), and
the nitride layer comprises silicon nitride (Si₃N₄).

16. The method of claim 13, further comprising:
forming a oxide on sidewalls and a bottom surface of the STI trench; and
forming a nitride liner on the oxide.

17. The method of claim 13, further comprising:
filling the STI trench with spin-on dielectric; and
densifying the spin-on dielectric within the STI trench.

18. The method of claim 17, wherein the spin-on dielectric comprises perhydrosilazane (SiH₂NH).

19. The method of claim 17, further comprising:
planarizing the spin-on dielectric with a top surface of the second portion of the substrate.

20. The method of claim 13, wherein;
the STI trench 212 has a depth of between 300 nm and 400 nm, and a width of between 250 nm and 400 nm, and
the one or more first trenches each have a depth of between 200 nm and 270 nm, and a width of between 40 nm and 60 nm.
